(19) United States
(12) Patent Application Publication
(10) Pub. No.: US 2019/0243190 A1
(43) Pub. Date: Aug. 8, 2019

(54) PIXEL ARRAY SUBSTRATE AND DISPLAY PANEL

(71) Applicant: Chunghwa Picture Tubes, LTD., Taoyuan City (TW)

(72) Inventors: Chen-De Lee, Taoyuan City (TW); Chun-Ming Huang, New Taipei City (TW); Chih-Chuan Chen, Taoyuan City (TW)

(73) Assignee: Chunghwa Picture Tubes, LTD., Taoyuan City (TW)

(21) Appl. No.: 15/955,708

(22) Filed: Apr. 18, 2018

(30) Foreign Application Priority Data
Feb. 8, 2018 (CN) 201810126103.0

(51) Int. Cl. G02F 1/1343; G02F 1/1333; G02F 1/1368; H01L 27/12

(52) U.S. Cl. CPC G02F 1/134309; G02F 1/133345; G02F 2201/123; H01L 27/1214; G02F 2201/121; G02F 1/1368

(57) ABSTRACT

A pixel array substrate includes a substrate, pixel units, and signal lines. Each pixel unit includes an active device, a first insulation layer, a common electrode, a second insulation layer, and a pixel electrode. The common electrode is disposed on the first insulation layer and has openings. The pixel electrode is disposed on the second insulation layer and overlapped with the common electrode. The pixel electrode is electrically connected to the active device. The signal lines are disposed on the substrate and electrically connected to the active device, respectively. The openings include at least one first opening, and an orthogonal projection of the at least one first opening on the substrate is located between orthogonal projections of the pixel electrodes on the substrate and orthogonal projections of the signal lines on the substrate. A display panel including the pixel array substrate is also provided.

### CROSS-REFERENCE TO RELATED APPLICATION

This application claims the priority benefit of China application serial no. 201810126103.0, filed on Feb. 8, 2018. The entirety of the above-mentioned patent application is hereby incorporated by reference herein and made a part of this specification.

### BACKGROUND

### Technical Field

The disclosure relates to a substrate and a panel; more particularly, the disclosure relates to a pixel array substrate and a display panel.

### Description of Related Art

Liquid crystal displays (LCD) are currently the mainstream products in the display industry. Taking a twisted nematic (TN) type LCD panel as an example, its viewing angle is about 120 degrees in the horizontal direction and about 90 degrees in the vertical direction, which cannot satisfy the needs of consumers. To break said bottleneck, various vendors have developed a variety of wide viewing angle technologies and applied the same to display panels, such as vertical alignment (VA) type display panels, in-plane switching (IPS) type display panels, and fringe field switching (FFS) type display panels.

In the FFS type display panel, for instance, the viewing angle issue existing in the conventional LCD panel has been resolved to great extent, and the FFS type display panel is characterized by low color shift. Generally, the FFS type display panel may be categorized into a top-corn FFS display panel and a middle-corn FFS display panel. The middle-corn FFS display panel satisfies the consumers' requirements for good taste. However, in the conventional middle-corn FFS display panel, when the voltage increases, the liquid crystal molecules are easily affected by the vertical electric field in the fringe electric field, which significantly increases the magnitude of the tilt angle of the liquid crystal molecules and decreases the light transmittance. Hence, a pixel substrate that can lessen the influence of the vertical electric field on the liquid crystal molecules and improve the transmittance of the display panel is deemed a solution to said issues which need to be solved in the pertinent art.

### SUMMARY

The disclosure is directed to a pixel array substrate and a display panel in which the magnitude of the tilt angle of the liquid crystal molecules may be reduced, thus increasing the light transmittance of the display panel, and improving performance of the display panel.

In an embodiment, a pixel array substrate including a substrate, a plurality of pixel units, and a plurality of signal lines is provided. The pixel units are arranged on the substrate, and each of the pixel units includes an active device, a first insulation layer, a common electrode, a second insulation layer, and a pixel electrode. The first insulation layer covers the active device. The common electrode is disposed on the first insulation layer, and the common electrode has a plurality of openings. The second insulation layer covers the common electrode and fills the openings. The pixel electrode is disposed on the second insulation layer and overlapped with the common electrode. The pixel electrode is electrically connected to the active device. The signal lines are disposed on the substrate and electrically connected to the active device, respectively. The openings include at least one first opening, and an orthogonal projection of the at least one first opening on the substrate is located between an orthogonal projection of the pixel electrode on the substrate and orthogonal projections of the signal lines on the substrate.

According to an embodiment, the signal lines include a plurality of first signal lines and a plurality of second signal lines. The first signal lines and the second signal lines are alternately arranged.

According to an embodiment, the orthogonal projection of the at least one first opening on the substrate is located between the orthogonal projection of the pixel electrode on the substrate and orthogonal projections of the first signal lines on the substrate.

According to an embodiment, an area of the orthogonal projections of the first signal lines on the substrate is completely located within an area of orthogonal projection of the common electrode on the substrate.

According to an embodiment, an area of the orthogonal projection of the pixel electrode on the substrate is smaller than an area of the orthogonal projection of the common electrode on the substrate.

According to an embodiment, the common electrode is overlapped with the first signal lines and the second signal lines.

According to an embodiment, a first distance is among the pixel electrodes of the pixel units, and the first distance has a fixed value.

According to an embodiment, the at least one first opening has a second distance parallel to the second signal lines, and the first distance is greater than the second distance.

According to an embodiment, a third distance is between the orthogonal projections of the first signal lines on the substrate and an orthogonal projection of a closest one of the at least one first opening on the substrate, the first distance is greater than the third distance, and the second distance is identical to or different from the third distance.

According to an embodiment, the pixel electrode has a plurality of slits overlapped with the common electrode.

According to an embodiment, patterns of the slits are rectangular or irregularly shaped.

According to an embodiment, a pattern of the at least one first opening is rectangular or irregularly shaped.

According to an embodiment, the common electrode further includes a second opening exposing the active device.

In an embodiment, a display panel including the aforesaid pixel array substrate, an opposite substrate, and a liquid crystal layer is provided. The opposite substrate is located opposite to the pixel array substrate. The liquid crystal layer is disposed between the pixel array substrate and the opposite substrate.

In view of the above, in the pixel array substrate and the display panel provided in one or more embodiments, the at least one first opening is disposed on the common electrode, and the orthogonal projection of the at least one first opening on the substrate is located between the orthogonal projections of the pixel electrodes on the substrate and the orthogonal projections of the first signal lines on the substrate. Hence, the at least one first opening enhances the stability of the fringe electric field of the pixel electrodes, lessens the influence of the vertical electric field on liquid crystal molecules, reduces the magnitude of the tilt angles of the liquid crystal molecules, and thereby increases the light transmittance. That is, the at least one first opening located between the pixel electrodes and the first signal lines solves the issue of the reduced light transmittance of the display panel caused by the rising voltage, whereby the pixel array substrate and the display panel are characterized by the improved display quality and performance.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top enlarged view illustrating a portion of a pixel array substrate according to an embodiment of the invention.

FIG. 2 is a schematic cross-sectional view taken along a sectional line A-A′ depicted in FIG. 1.

FIG. 3 is a schematic cross-sectional view taken along a sectional line B-B′ depicted in FIG. 1.

FIG. 4 is a schematic top enlarged view illustrating a portion of a pixel array substrate according to another embodiment of the invention.

FIG. 5 is a schematic cross-sectional view of a display panel according to an embodiment of the invention.

### DESCRIPTION OF THE EMBODIMENTS

Reference will now be made in detail to the exemplary embodiments of the invention, examples of which are illustrated in accompanying figures. Wherever possible, identical reference numbers are used in figures and descriptions to refer to identical or similar parts.

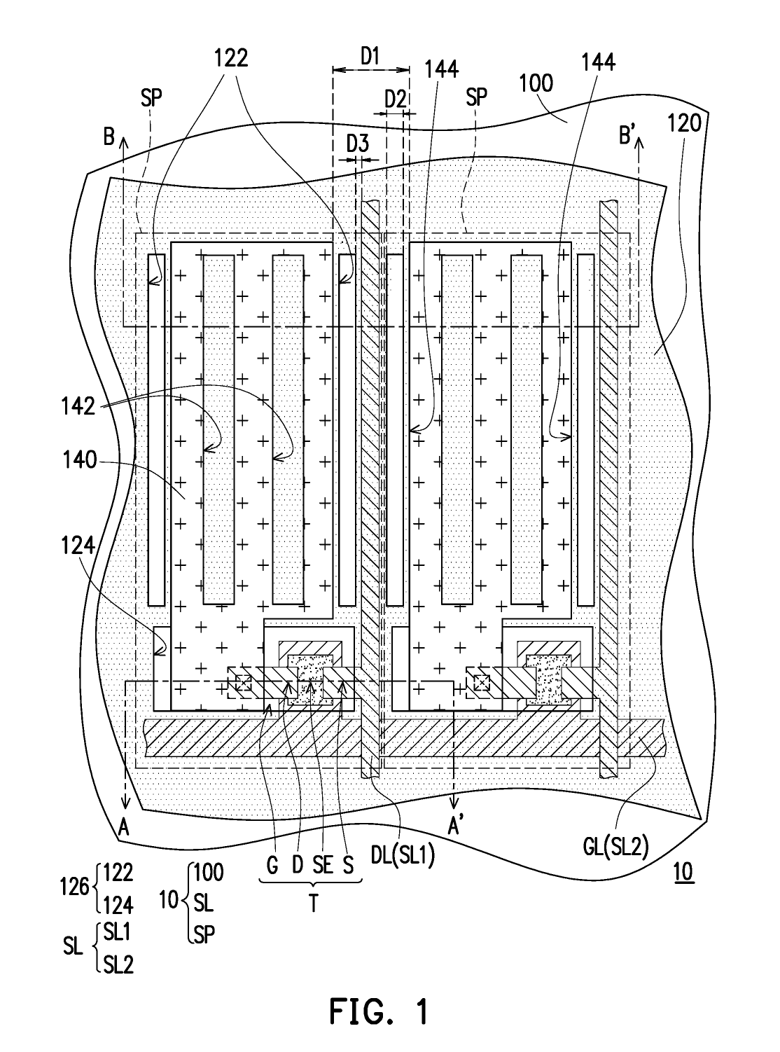

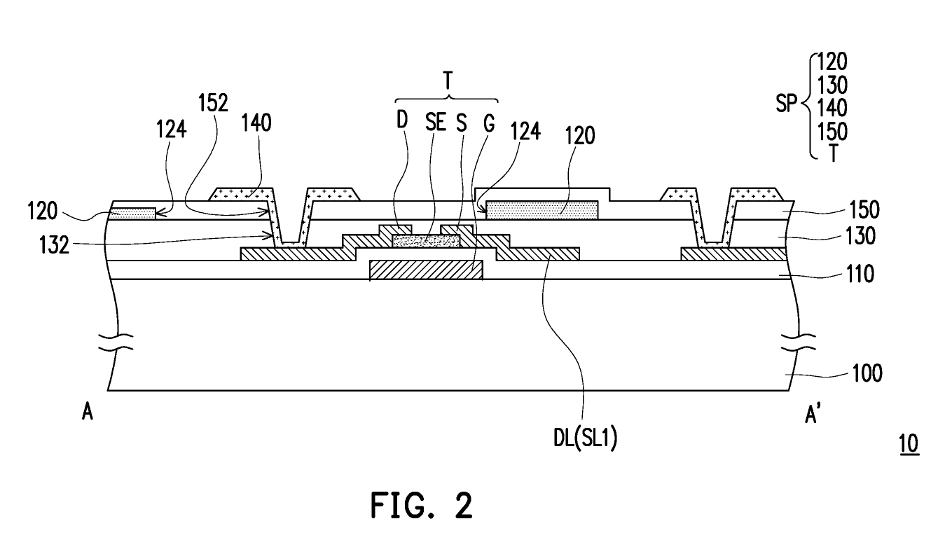

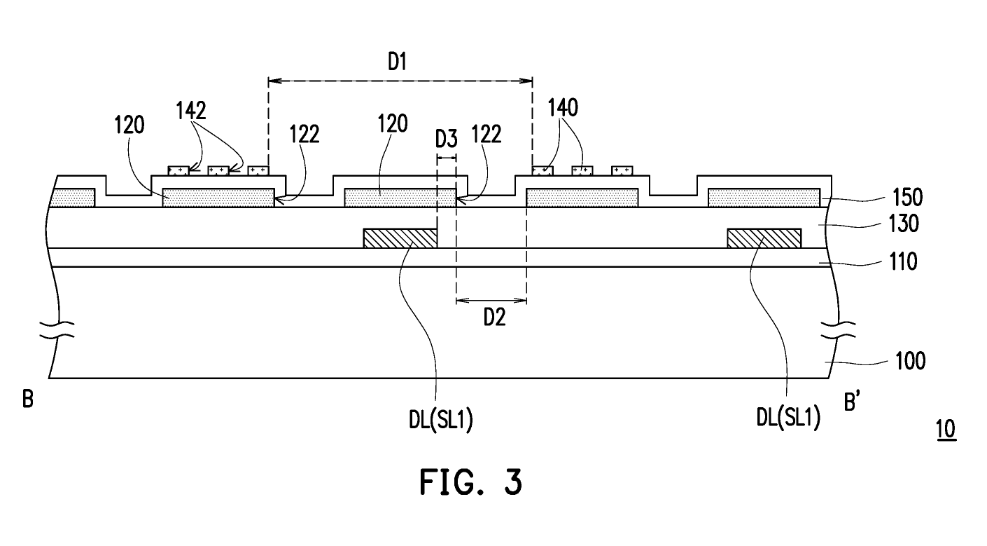

FIG. 1 is a schematic top enlarged view illustrating a portion of a pixel array substrate according to an embodiment of the invention. FIG. 2 is a schematic cross-sectional view taken along a sectional line A-A′ depicted in FIG. 1. FIG. 3 is a schematic cross-sectional view taken along a sectional line B-B′ depicted in FIG. 1. With reference to FIG. 1 and FIG. 2, a pixel array substrate 10 includes a substrate 100, a plurality of pixel units SP, and a plurality of signal lines SL. The pixel units SP are disposed on the substrate 100 and arranged in array on the substrate 100. In the present embodiment, the substrate 100 may be a transparent substrate, such as a glass substrate, a quartz substrate, a plastic substrate, or another substrate made of appropriate materials. This should however not be construed as a limitation in the disclosure; in other embodiments, the substrate 100 may also be made of a non-transparent/reflective material, e.g., a conductive material, a large chip, a ceramic material, or any other appropriate material.

Note that two adjacent pixel units SP are exemplarily depicted in FIG. 1; since people skilled in the pertinent art are able to implement the pixel array substrate 10 according to FIG. 1, FIG. 2, and the descriptions provided herein, it is not necessary to show all of the pixel units SP in the drawings. In the present embodiment, each of the pixel units SP includes an active device T, a common electrode 120 having a plurality of openings 126, a pixel electrode 140 overlapped with the common electrode 120, an active device T electrically connected to the pixel electrode 140, a first insulation layer 130, and a second insulation layer 150. According to the present embodiment, the pixel units SP and the signal lines SL are disposed on the substrate 100, and the signal lines SL are electrically connected to the active device T, respectively. Particularly, the signal lines SL include a plurality of first signal lines SL1 and a plurality of second signal lines SL2. The first signal lines SL1 and the second signal lines SL2 are alternately arranged on the substrate 100. For instance, the first signal lines SL1 are data lines DL, and the second signal lines SL2 are gate lines GL, for instance. The active device T is electrically connected to the data lines DL and the gate lines GL, which should however not be construed as a limitation in the disclosure. For clarity purposes, the first insulation layer 130 and the second insulation layer 150 are omitted in FIG. 1 but are depicted in FIG. 2.

With reference to FIG. 1 and FIG. 2, the active device T provided in the present embodiment includes a thin film transistor (TFT). The active device T has a gate G, a semiconductor pattern SE overlapped with the gate G, and a source S and a drain D electrically connected to two sides of the semiconductor pattern SE, respectively. The gate G is electrically connected to the gate lines GL (also referred to as the second signal lines SL2). The source S is electrically connected to the data lines DL (also referred to as the first signal lines SL1). The drain D is electrically connected to the pixel electrode 140. In the present embodiment, the active device T may selectively include a gate insulation layer 110 disposed on the gate G, so as to separate the semiconductor pattern SE from the gate G. According to the present embodiment, the gate G and the gate lines GL may selectively belong to the same layer, and the source S and the data lines DL may selectively belong to the same layer; however, the disclosure is not limited thereto. The gate G provided in the present embodiment is located below the semiconductor pattern SE. Namely, the active device T provided in the present embodiment may be a bottom gate TFT, which should however not be construed as a limitation in the disclosure; in other embodiments, the active device T may be a top gate TFT or a device of another appropriate form.

According to the present embodiment, in consideration of conductivity, the gate lines GL and the data lines DL are made of metallic materials, which should not be construed as a limitation in the disclosure; in other embodiments, the gate lines GL and the data lines DL may also be made of other conductive materials, such as an alloy, a metal nitride material, a metal oxide material, a metal oxynitride material, or a stacked layer having the metal material and other conductive materials. The semiconductor pattern SE may have a single-layer structure or a multi-layer structure including amorphous silicon, polysilicon, microcrystalline silicon, monocrystalline silicon, an organic semiconductor material, an oxide semiconductor material (e.g., indium zinc oxide, indium zinc germanium oxide, other suitable materials, or a combination of the above), other suitable materials, the aforesaid material containing dopants, or combinations thereof.

With reference to FIG. 1 and FIG. 2, the common electrode 120 is disposed on the substrate 100 and overlapped with the first signal lines SL1 and the second signal lines SL2. Specifically, as shown in FIG. 2, the first insulation layer 130 covers the active device T and the signal lines SL. The common electrode 120 are disposed on the first insulation layer 130 and have a plurality of openings 126 exposing the first insulation layer 130 and the underlying active device T. The second insulation layer 150 is disposed on the entire surface of the substrate 100, covers the common electrode 120, and fills the openings 126. In this embodiment, the openings 126 include at least one first opening 122 and a second opening 124. The second insulation layer 150 provided in the present embodiment further covers the signal lines SL and the active device T. The first insulation layer 130 and the second insulation layer 150 may be made of an inorganic material (such as silicon oxide, silicon nitride, silicon oxynitride, or a stacked layer having at least two of the foregoing materials), an organic material, or a combination thereof.

In the present embodiment, the pixel electrodes 140 are electrically connected to the active device T. With reference to FIG. 1 and FIG. 2, the pixel electrodes 140 are disposed on the second insulation layer 150 and partially overlapped with the common electrode 120. Parts of the pixel electrodes 140 extend and are overlapped with the second opening 124. The first insulation layer 130 and the second insulation layer 150 respectively have through holes 132 and 152, which expose a portion of the active device T in the second opening 124. The pixel electrodes 140 fill the through holes 132 and 152 and electrically connected to the drain D of the active device T. In this embodiment, the pixel electrodes 140 are transparent electrodes, for example. The transparent electrodes may be made of metal oxide, e.g., indium tin oxide, indium zinc oxide, aluminum tin oxide, aluminum zinc oxide, indium zinc germanium oxide, other suitable oxides, or a stacked layer having at least two of the aforesaid materials. This should however not be construed as a limitation in the disclosure; in other embodiments, the pixel electrodes 140 may also be non-transparent/reflective electrodes. The material of the non-transparent/reflective electrodes is metal, for instance, which should not be construed as a limitation in the disclosure.

With reference to FIG. 1 and FIG. 3, in the present embodiment, the pixel electrodes 140 have a plurality of slits 142 overlapped with the common electrode 120, and patterns of the slits 142 observed from the top are rectangular. However, the disclosure is not limited thereto. An area of orthogonal projections of the pixel electrodes 140 on the substrate 100 is smaller than an area of orthogonal projection of the common electrode 120 on the substrate 100. The pixel electrodes 140 are electrically isolated from the common electrode 120 through the second insulation layer 150.

In the present embodiment, note that the common electrode 120 of each pixel unit SP includes at least one first opening 122, and an orthogonal projection of the at least one first opening 122 on the substrate 100 is located between an orthogonal projection of the pixel electrode 140 on the substrate 100 and orthogonal projections of the first signal lines SL1 on the substrate 100. For instance, as shown in FIG. 1 and FIG. 3, the common electrode 120 of each pixel unit SP selectively includes two first openings 122 respectively located between two opposite long sides 144 of the pixel electrode 140 and the closest first signal lines SL1 corresponding to each of the long sides 144. That is, the first openings 122 are disposed on the common electrode 120 between the orthogonal projection of the pixel electrode 140 on the substrate 100 and the orthogonal projections of the first signal lines SL1 on the substrate 100. In the present embodiment, the first openings 122 are arranged along the long sides 144, and patterns of the first openings 122 observed from the top are rectangular; however, the disclosure is not limited thereto. Two first openings 122 in each pixel unit SP are schematically shown in FIG. 1 and FIG. 3, which should not be construed as a limitation in the disclosure; in other embodiments, each pixel unit SP may merely include one first opening 122 or a plurality of first openings 122.

Specifically, with reference to FIG. 1 and FIG. 3, an area of the orthogonal projections of the first signal lines SL1 on the substrate 100 is completely located within an area of the orthogonal projection of the common electrode 120 on the substrate 100 and between two adjacent pixel electrodes 140. The orthogonal projections of the first openings 122 of two adjacent pixel units SP on the substrate 100 are respectively located between the orthogonal projections of the two adjacent pixel electrodes 140 on the substrate 100 and the orthogonal projections of the first signal lines SL1 (which is between the adjacent pixel electrodes 140) on the substrate 100. That is, the orthogonal projections of two adjacent first openings 122 on the substrate 100 are respectively located on both sides of the orthogonal projections of the first signal lines SL1 on the substrate 100.

In particular, a first distance D1 is between the pixel electrodes 140 of the adjacent pixel units SP, and the first distance D1 has a fixed value. The first openings 122 have a second distance D2 therebetween, where the second distance D2 is parallel to the second signal lines SL2. The first distance D1 is greater than the second distance D2. For instance, the second distance D2 may be the width of one first opening 122, which should however not be construed as a limitation in the disclosure. That is, the distance between the pixel electrodes 140 is greater than the width of the first opening 122. According to an embodiment, a third distance D3 is between the orthogonal projections of the first signal lines SL1 on the substrate 100 and the orthogonal projections of the closest first openings 122 on the substrate corresponding to the first signal lines SL1, and the second distance D2 is identical to or different from the third distance D3. For instance, in the present embodiment, the third distance D3 may be less than the second distance D2 or may be equal to or greater than the second distance D2, and the first distance D1 is greater than the third distance D3. That is, the area of the orthogonal projections of the first signal lines SL1 on the substrate 100 is completely located within the area of the orthogonal projection of the common electrode 120 on the substrate 100, and the orthogonal projections of the first openings 122 on the substrate 100 are not overlapped with the orthogonal projections of the first signal lines SL1 on the substrate 100.

In view of said arrangement, the common electrode 120 of each pixel unit SP provided in the present embodiment has at least one first opening 122 between the pixel electrode 140 and the first signal lines SL1; hence, when the voltage increases, the influence of the vertical electric field at the periphery of the pixel electrode 140 on the liquid crystal molecules (not shown) may be lessened, so as to enhance the stability of the fringe electric field of the pixel electrode 140, reduce the magnitude of the tilt angle of the liquid crystal molecules, further increase the light transmittance, and accordingly improve the display quality of the pixel array substrate 10.

Note that the reference numbers and some contents of the foregoing embodiments are also applied in the following embodiments, in which the same reference numbers are used to designate the same or similar device. Descriptions of the same technical contents may be referred to as those provided above and thus will not be repeated in the following embodiments.

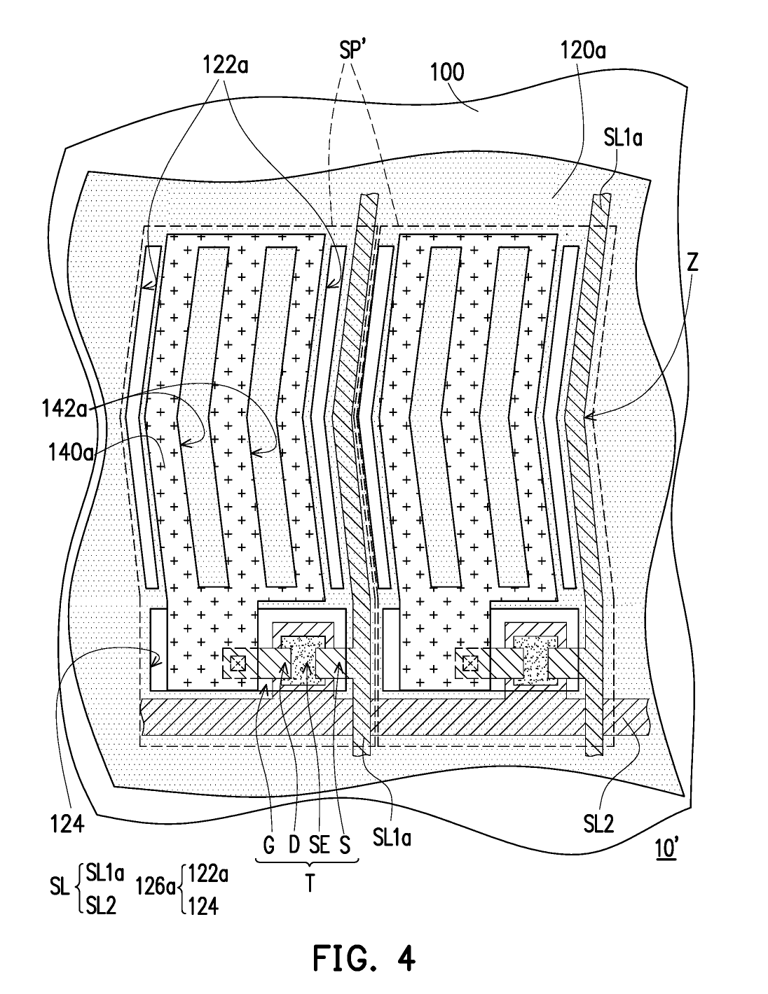

FIG. 4 is a schematic top enlarged view illustrating a portion of a pixel array substrate according to another embodiment of the invention. With reference to FIG. 1 and FIG. 4, the pixel array substrate 10′ provided in the present embodiment is similar to the pixel array substrate 10 depicted in FIG. 1, and the difference therebetween lies in that an included angle Z is between the first signal lines SL1a of each pixel unit SP′ according to the present embodiment, and the openings 126a include a plurality of first openings 122a conformal to the first signal lines SL1a. Particularly, in the present embodiment, when the first signal lines SL1a extend along a direction away from the second signal lines SL2, the first signal lines SL1a may first move toward the pixel electrodes 140a and then move away from the pixel electrodes 140a, so as to form the included angle Z which is smaller than 180°. For instance, patterns of the first signal lines SL1a observed from the top may be irregularly shaped. In particular, the irregular shape of the patterns of the first signal lines SL1a may be a wing-like shape, for instance; however, the disclosure is not limited thereto. In other embodiments, the irregular shape of the patterns of the first signal lines SL1a may also be a curved or bent bar shape. The pixel electrodes 140a and the slits 142a overlapped with the common electrode 120a are arranged along the patterns of the first signal lines SL1a. That is, the patterns of the pixel electrodes 140a and the slits 142a observed from the top may also be irregularly shaped. In particular, the irregular shape of the patterns of the pixel electrodes 140a and the slits 142a may be a wing-like shape, for instance; however, the disclosure is not limited thereto. In other embodiments, the irregular shape of the patterns of the pixel electrodes 140a and the slits 142a may also be a curved or bent bar shape. Besides, the openings 126a include a plurality of first openings 122a and second opening 124. The first openings 122 formed between the orthogonal projections of the pixel electrodes 140a on the substrate 100 and the orthogonal projections of the first signal lines SL1a on the substrate 100 are arranged along the patterns of the first signal lines SL1a. That is, the patterns of the first openings 122a observed from the top may also be irregularly shaped. In particular, the irregular shape of the patterns of the first openings 122a may be a wing-like shape, for instance; however, the disclosure is not limited thereto. In other embodiments, the irregular shape of the patterns of the first openings 122a may also be a curved or bent bar shape. The second opening 124 expose the active device T.

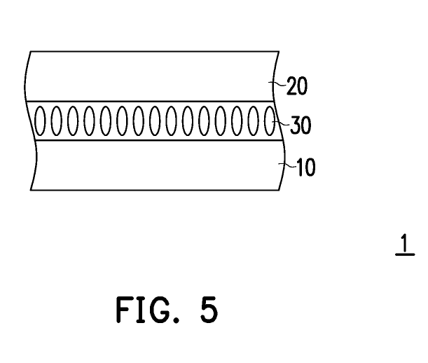

FIG. 5 is a schematic cross-sectional view of a display panel according to an embodiment of the invention. With reference to FIG. 5, the display panel 1 includes the aforesaid pixel array substrate 10, an opposite substrate 20 located opposite to the pixel array substrate 10, and a liquid crystal layer 30 located between the pixel array substrate 10 and the opposite substrate 20. According to the present embodiment, the opposite substrate 20 may be a color filter substrate. However, the disclosure is not limited thereto; in other embodiments, the opposite substrate 20 may not include any color filter, and the color filter may be integrated onto the pixel array substrate 10 to form a so-called color filter on array (COA) structure. Since the display panel 1 is equipped with the aforesaid pixel array substrate 10 with said special design, the pixel array 10 may solve the issue of the reduced light transmittance of the display panel 1 caused by the rising voltage, whereby the display panel 1 is characterized by the improved display quality and performance.

To sum up, in the pixel array substrate and the display panel provided in one or more embodiments of the invention, the common electrode of each pixel unit includes at least one first opening. The orthogonal projection of the at least one first opening on the substrate is located between the orthogonal projections of the pixel electrodes on the substrate and the orthogonal projections of the first signal lines on the substrate. The orthogonal projection of the common electrode on the substrate completely cover the orthogonal projections of the first signal lines on the substrate, and the orthogonal projections of the first openings of the adjacent pixel units on the substrate are respectively located on two sides of the orthogonal projections of the pixel electrodes of the adjacent pixel units. The orthogonal projection of the at least one first opening on the substrate is not overlapped with the orthogonal projections of the first signal lines on the substrate. Hence, the openings may be formed on the common electrode between the pixel electrodes and the first signal lines, so as to lessen the influence of the vertical electric field on the liquid crystal molecules while the voltage increases, reduce the magnitude of the tilt angles of the liquid crystal molecules, and thereby increases the light transmittance. Furthermore, the stability of the fringe electric field of the pixel electrodes may be enhanced. That is, the at least one first opening located between the pixel electrodes and the first signal lines solves the issue of the reduced light transmittance of the display panel caused by the rising voltage, whereby the pixel array substrate and the display panel are characterized by the improved display quality and performance.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A pixel array substrate comprising:
a substrate;
a plurality of pixel units, arranged in array on the substrate, each of the plurality of pixel units comprising:
an active device;
a first insulation layer covering the active device;
a common electrode disposed on the first insulation layer and having a plurality of openings;
a second insulation layer covering the common electrode and filling the plurality of openings; and
a pixel electrode disposed on the second insulation layer and overlapped with the common electrode, wherein the pixel electrode is electrically connected to the active device; and
a plurality of signal lines disposed on the substrate and electrically connected to the active device, respectively,
wherein each of the openings comprises at least one first opening, and an orthogonal projection of the at least one first opening on the substrate is located between an orthogonal projection of the pixel electrode on the substrate and orthogonal projections of the plurality of signal lines on the substrate.

2. The pixel array substrate according to claim 1, wherein the plurality of signal lines comprising a plurality of first signal lines and a plurality of second signal lines, the plurality of first signal lines and the plurality of second signal lines being alternately arranged.

3. The pixel array substrate according to claim 2, wherein the orthogonal projection of the at least one first opening on the substrate is located between the orthogonal projection of the pixel electrode on the substrate and orthogonal projections of the plurality of first signal lines on the substrate.

4. The pixel array substrate according to claim 2, wherein an area of the orthogonal projections of the plurality of first signal lines on the substrate is completely located within an area of orthogonal projection of the common electrode on the substrate.

5. The pixel array substrate according to claim 2, wherein an area of the orthogonal projection of the pixel electrode on the substrate is smaller than an area of the orthogonal projection of the common electrode on the substrate.

6. The pixel array substrate according to claim 2, wherein the common electrode being overlapped with the plurality of first signal lines and the plurality of second signal lines.

7. The pixel array substrate according to claim 2, wherein a first distance is among the pixel electrodes of the plurality of pixel units, and the first distance has a fixed value.

8. The pixel array substrate according to claim 7, wherein the at least one first opening has a second distance parallel to the plurality of second signal lines, and the first distance is greater than the second distance.

9. The pixel array substrate according to claim 8, wherein a third distance is between the orthogonal projections of the plurality of first signal lines on the substrate and an orthogonal projection of a closest one of the at least one first opening on the substrate, the first distance is greater than the third distance, and the second distance is identical to or different from the third distance.

10. The pixel array substrate according to claim 1, wherein the pixel electrode has a plurality of slits overlapped with the common electrode.

11. The pixel array substrate according to claim 10, wherein patterns of the plurality of slits are rectangular or irregularly shaped.

12. The pixel array substrate according to claim 11, wherein a pattern of the at least one first opening is rectangular or irregularly shaped.

13. The pixel array substrate according to claim 1, wherein the common electrode further comprising a second opening exposing the active device.

14. A display panel comprising:
the pixel array substrate provided in claim 1;
an opposite substrate located opposite to the pixel array substrate; and
a liquid crystal layer disposed between the pixel array substrate and the opposite substrate.
